(19) United States
(12) Patent Application Publication
(10) Pub. No.: US 2008/0084677 A1
(43) Pub. Date: Apr. 10, 2008

(54) ELECTRONIC APPARATUS

(75) Inventors: Chih-Long Ho, Taipei Hsien (TW); Ming-Lin Tsai, Taipei Hsien (TW); Kwun-Yao Ho, Taipei Hsien (TW); Moriss Kung, Taipei Hsien (TW)

Correspondence Address: J C PATENTS, INC., 4 VENTURE, SUITE 250, IRVINE, CA, 92618, US

(73) Assignee: VIA TECHNOLOGIES, INC., Taipei Hsien (TW)

(21) Appl. No.: 11/616,661

(22) Filed: Dec. 27, 2006

(30) Foreign Application Priority Data
Oct. 4, 2006 (TW) 95136842

(51) Int. Cl. H05K 7/00

(52) U.S. Cl. 361/760

(57) ABSTRACT

An electronic apparatus including a substrate, a baseband component and an electronic assembly is disclosed. The substrate has a first surface and a second surface opposite to the first surface. The baseband component is disposed on the first surface and electrically connected to the substrate. The electronic assembly includes an integrated passive device and a radio frequency component. The integrated passive device is disposed on the second surface and electrically connected to the substrate. The radio frequency component is disposed on the integrated passive device and electrically connected to the integrated passive device.

### CROSS-REFERENCE TO RELATED APPLICATION

This application claims the priority benefit of Taiwan application serial no. 95136842, filed on Oct. 4, 2006. All disclosure of the Taiwan application is incorporated herein by reference.

### BACKGROUND OF THE INVENTION

1. Field of the Invention

The present invention generally relates to an electronic apparatus, and more particular, to an electronic apparatus having a smaller volume and a higher layout density of the internal components thereof.

2. Description of Related Art

In order to adapt an electronic product to the trend of light-thin-smallish, pro high frequency, pro module design and multifunction, the integration of electronic components and electronic sub-assemblies need to be accordingly advanced, and to achieve this goal, the technology development of the new-age high frequency broadband materials and components is the key for success in future. Regarding to the integration, it has reached to the system in package (SIP) level nowadays by the breakthrough of the new package materials, the development of the new processes and the integration of the design approaches. In recent days, further development on the high frequency chip devices, the integrated passive devices (IPDs), the micro-electro-mechanical systems (MEMSes) and the nanomaterial technology are being endeavoured for establishing the integration module technology and advancing the efficiency of high frequency broadband products.

FIG. 1 is a 3D-diagram of a conventional electronic apparatus. Referring to FIG. 1, a conventional electronic apparatus 100 includes a substrate 110, a baseband component (BB component) 120, a plurality of passive devices 130, a radio frequency component (RF component) 140, an antenna 150 and a universal serial bus port (USB port) 160. The BB component 120, the passive devices 130 and the RF component 140 are disposed on the substrate 110 by using the surface mounting technology (SMT) and electrically connected to the substrate 110. The conventional electronic apparatus 100 is used to conduct wireless communications with external other electronic apparatuses (not shown) through the antenna 150.

However, since the BB component 120, the passive devices 130 and the RF component 140 disposed on the substrate 110 by using the SMT need a bigger connection area, the cost of the USB port 160 is accordingly higher and requires a low voltage with fixed specifications to be driven, and the passive devices 130 are respectively disposed on the substrate 110 which leads to a more complex process, therefore, the conventional electronic apparatus 100 needs to be improved.

### SUMMARY OF THE INVENTION

The present invention is directed to an electronic apparatus having a smaller volume and a higher layout density of the internal components thereof.

The present invention provides an electronic apparatus, which includes a baseband module (BB module), a radio frequency module (RF module), at least an connection member, a first communication component and a second communication component. The BB module is electrically connected to the RF module through the connection members. The first communication component is disposed on the BB module and the second communication component is disposed on the RF module.

The present invention provides an electronic apparatus, which includes a substrate, a BB component and an electronic assembly. The substrate has a first surface and a second surface opposite to the first surface. The BB component is disposed on the first surface and electrically connected to the substrate. The electronic assembly includes an IPD and an RF component, wherein the IPD is disposed on the second surface and electrically connected to the substrate and the RF component is disposed on the IPD and electrically connected to the IPD.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a 3D-diagram of a conventional electronic apparatus.

FIG. 2A is a side view of an electronic apparatus according to a first embodiment of the present invention.

FIG. 2B is a side view of another electronic apparatus according to the first embodiment of the present invention.

FIG. 3 is a side view of an electronic apparatus according to a second embodiment of the present invention.

FIG. 4 is a side view of an electronic apparatus according to a third embodiment of the present invention.

FIG. 5 is a side view of an electronic apparatus according to a fourth embodiment of the present invention.

FIG. 6 is a side view of an electronic apparatus according to a fifth embodiment of the present invention.

FIG. 7 is a side view of an electronic apparatus according to a sixth embodiment of the present invention.

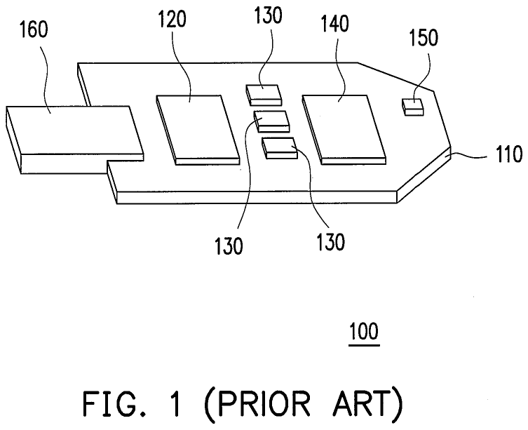

### DESCRIPTION OF THE EMBODIMENTS

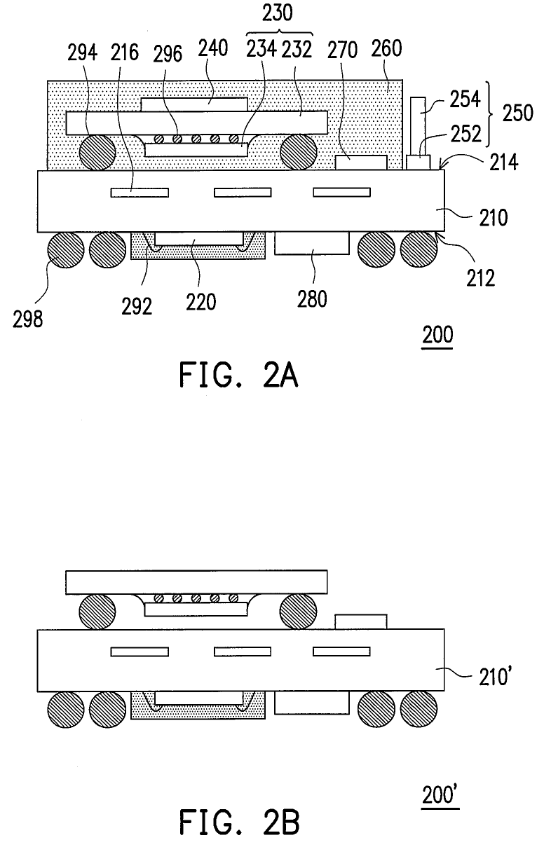

Referring to FIG. 2A, FIG. 2A is a side view of an electronic apparatus according to a first embodiment of the present invention. The electronic apparatus 200 of the first embodiment includes a substrate 210, a baseband (BB) component 220 and an electronic assembly 230. The substrate 210 has a first surface 212 and a second surface 214 opposite to the first surface 212. The BB component 220 is disposed on the first surface 212 and electrically connected to the substrate 210. The electronic assembly 230 includes an integrated passive device (IPD) 232 and a radio-frequency (RF) component 234, wherein the IPD 232 is disposed on the second surface 214 and electrically connected to the substrate 210. The RF component 234 is disposed on the IPD 232 and electrically connected to the IPD 232. Besides, the electronic apparatus 200 further includes an antenna 240 electrically connected to the substrate 210 or the IPD 232.

A BB module is composed of the substrate 210 and the BB component 220, and the electronic assembly 230 comprising the IPD 232 and the RF component 234 can serve as an RF module. The so-called IPD 232 is an electronic device having an independent function by integrating a plurality of passive devices (not shown). The basic operation of the electronic apparatus 200 may be described as follows. If the antenna 240 receives a high frequency signal, a band signal of the high frequency signal is extracted and impedance matching is processed by the IPD 232. Then the extracted and matched band signal is sent to a low noise amplifier (LNA) (not shown) of the RF component 234. Next, the band signal is transferred to the BB component 220 for further signal processing. On the other hand, the BB component 220 can also transfer a signal to the power amplifier (PA) (not shown) of the RF component 234, and the transferred signal is processed and filtered by the IPD 232 and transmitted by the antenna 240.

In the first embodiment, the antenna 240 can be a chip antenna, which is disposed on the IPD 232 or on the substrate 210. The antenna 240 can also be an F-shaped circuit antenna, which comprises an F-shaped wiring pattern of a wiring layer (not shown) of the substrate 210 or of the IPD 232. The antenna 240, regardless of being a chip antenna or an F-shaped circuit antenna, may be a built-in antenna.

In the first embodiment, the electronic apparatus 200 further includes an antenna connector 252, another antenna 254 and encapsulant 260. The antenna connector 252 is disposed on the substrate 210, but can be also disposed on the IPD 232. The antenna 254 is an external antenna, which can be plugged and fixed into the antenna connector 252 and electrically connected to the antenna connector 252. A communication component 250 is composed of the antenna 254 and the antenna connector 252. The encapsulant 260 encapsulates at least the electronic assembly 230 and a part of the second surface 214 of the substrate 210 to expose the antenna connector 252. If the external antenna 254 is plugged into the antenna connector 252 of the electronic apparatus 200, the above-mentioned built-in antenna 240 can be replaced by the external antenna 254 which has the function of the built-in antenna 240. In addition, the external antenna 254 is able to enhance the functions of transmitting and receiving signals of the electronic apparatus 200. Obviously, both the antennas 240 and 254 can be simultaneously functioned to meet the multifunctional requirement of transmitting and receiving the signals.

FIG. 2B is a side view of another electronic apparatus according to the first embodiment of the present invention. Referring to FIGS. 2A and 2B, compared to the electronic apparatus 200 shown in FIG. 2A, the electronic apparatus 200′ shown in FIG. 2B is designed to have no antenna 240 and the communication component 250, such that the electronic apparatus 200′ has a comparatively smaller volume. In addition, if the substrate 210′ of the electronic apparatus 200′ is electrically connected to an electronic apparatus that is below the electronic apparatus 200′, the electronic apparatus 200′ can utilizes another antenna, located in the electronic apparatus (that is below the the electronic apparatus 200′), as a media to transmit and receive signals.

Referring to FIG. 2A, the electronic apparatus 200 of the first embodiment further includes at least one passive device 270 and a memory device 280. The memory device 280 can be disposed on the first surface 212 of the substrate 210. The passive device 270 can be disposed on the second surface 214 of the substrate 210. And both of the memory device 280 and the passive device 270 are electrically connected to the substrate 210. It can be seen from FIG. 2A in more detail that the memory device 280 and the BB component 220 may be disposed on one side of the substrate 210, while the passive device 270, the electronic assembly 230 (i.e. the RF module) and the communication component 250 may be disposed on another side of the substrate 210. In addition, the substrate 210 may have at least an embedded electronic element 216 that may be an active element or a passive element. It should be noted that if the number of the passive devices are required to be increased and if the added passive devices are difficult to be integrated into an IPD 232, the above-mentioned passive device 270 may be disposed on the substrate 210, or, for example, an embedded electronic element 216 serving as a passive element may be disposed inside the substrate 210. Besides, the passive device 270 may be disposed on the IPD 232 according to the design requirements.

Referring to FIG. 2A again, the electronic apparatus 200 further includes a plurality of electrical connection members 292, a plurality of electrical connection members 294, a plurality of electrical connection members 296 and a plurality of electrical connection members 298. The BB component 220 is electrically connected to the substrate 210 through the electrical connection members 292. The IPD 232 is electrically connected to the substrate 210 through the electrical connection members 294. The RF component 234 is electrically connected to the IPD 232 through the electrical connection members 296. And the substrate 210 is electrically connected to an underlying electronic apparatus (not shown) through the electrical connection members 298. In the embodiment, the electrical connection members 292 may be bonding wires. For instance, the BB component 220 and the substrate 210 are electrically connected to each other by using the wire bonding technology. Then, the electrical connection members 294 may be solder balls made of tin, lead or tin-lead alloy. The electrical connection members 296 may be bumps made of tin, lead or tin-lead alloy. For example, the RF component 234 and the IPD 232 are electrically connected to each other by using the flip chip bonding technology. Additionally, the electrical connection members 298 may be solder balls. In terms of the relative position shown in FIG. 2A, the RF component 234 is located between the IPD 232 and the substrate 210.

It should be noted that the RF component 234 and the IPD 232 can be electrically connected to each other by using the surface mounting technology (SMT). For instance, they, 234 and 232, are electrically connected to each other through solder paste (not shown). Besides, the BB component 220 can also be electrically connected to the substrate 210 by using the SMT (not shown).

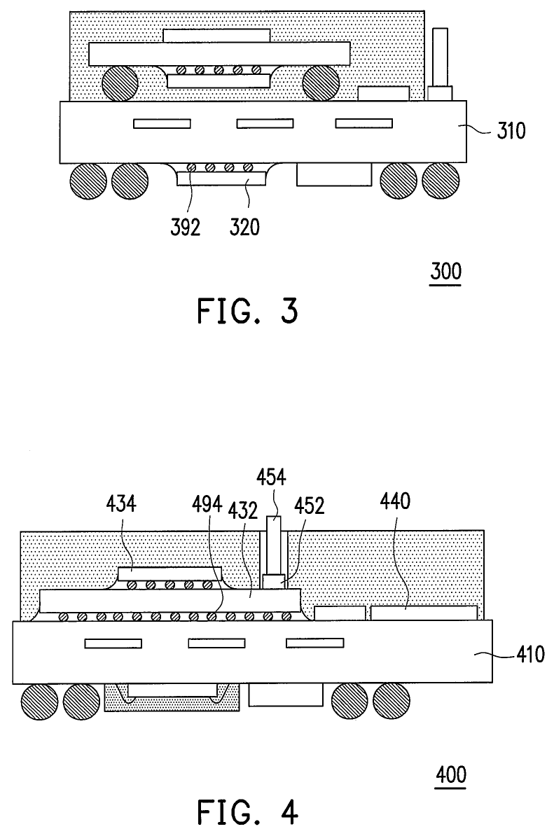

FIG. 3 is a side view of an electronic apparatus according to a second embodiment of the present invention. Referring to FIG. 3, the difference between the electronic apparatus 300 of the second embodiment and the electronic apparatus 200 of the first embodiment mainly is that the electrical connection members 392 for electrically connecting the BB component 320 to the substrate 310 may be bumps.

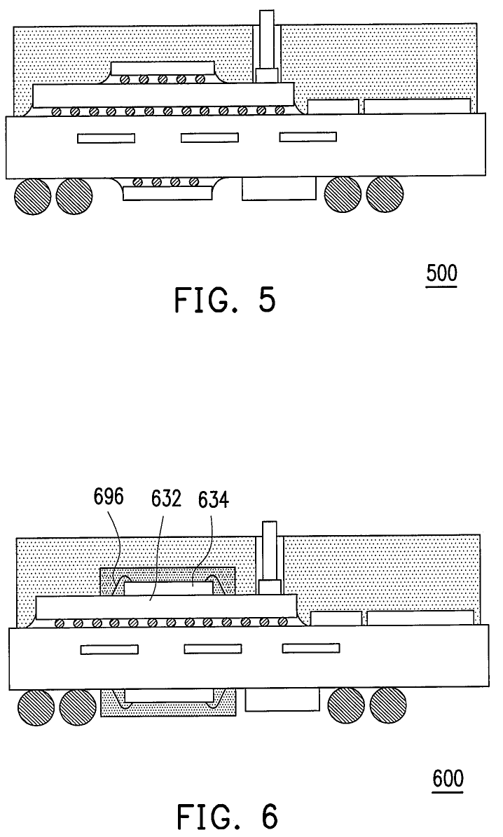

FIG. 4 is a side view of an electronic apparatus according to a third embodiment of the present invention. FIG. 5 is a side view of an electronic apparatus according to a fourth embodiment of the present invention. Referring to FIGS. 4 and 5, the differences between the electronic apparatus 400 of the third embodiment and the electronic apparatuses 200 and 300 of the above-mentioned embodiments mainly are as follows. The electrical connection members 494 for electrically connecting the IPD 432 to the substrate 410 may be bumps. The external antenna 454 and the antenna connector 452 may be disposed on the IPD 432. And the built-in antenna 440 may be disposed on the substrate 410. In addition, in terms of the relative position shown in FIG. 4, the IPD 432 is located between the RF component 434 and the substrate 410. The major difference between the electronic apparatus 500 of the fourth embodiment and the electronic apparatus 400 of the third embodiment is similar to the major difference between the electronic apparatus 300 of the second embodiment and the electronic apparatus 200 of the first embodiment. Thus, the description thereof is omitted.

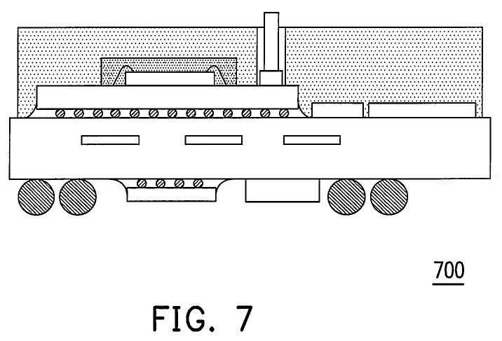

FIG. 6 is a side view of an electronic apparatus according to a fifth embodiment of the present invention. FIG. 7 is a side view of an electronic apparatus according to a sixth embodiment of the present invention. Referring to FIGS. 6 and 7, the difference between the electronic apparatus 600 of the fifth embodiment and the electronic apparatuses 400 and 500 of the above-mentioned embodiments mainly is that the electrical connection members 696 for electrically connecting RF component 634 to the IPD 632 may be bonding wires. The major difference between the electronic apparatus 700 of the sixth embodiment and the electronic apparatus 600 of the fifth embodiment is similar to the major difference between the electronic apparatus 500 of the fourth embodiment and the electronic apparatus 400 of the third embodiment. Thus, detail description thereof is omitted.

It should be note that in the above-described embodiments, an IPD is formed by integrating a plurality of active devices and a plurality of passive devices on/into a substrate, and an integrated device module with a specific function is fabricated using the process used for fabricating the passive device. In addition, the IPD may comprise only at least a passive device without active device or some other devices except the active device or the passive device. The method for fabricating an IPD includes at least the low temperature co-fired ceramics (LTCC) process, the thin film technology and the embedding process, etc.

In summary, the electronic apparatus of the present invention has at least the following advantages:

1. Since the components of the electronic apparatus provided by the present invention are interconnected to each other by using the electric interconnection technologies except the SMT, thus, the connection area required by the components of the electronic apparatus is comparatively smaller, and thereby reducing volume and increasing layout density of the internal components of the electronic apparatus.

2. Since the electronic apparatus of the present invention can be electrically connected to a next-level electronic apparatus through solder balls, not a USB port, thus, the driving voltage required by the electronic apparatus is more flexible and the cost reduced.

3. Since the electronic apparatus of the present invention adopts an IPD, thus, the electronic apparatus needs a fewer components for assembling and shorter process time.

4. Since the electronic apparatus of the present invention allows having at least two antennas, thus, the electronic apparatus has more function choices.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An electronic apparatus, comprising:
a baseband module comprising a substrate and a baseband component electrically connected to the substrate;
a radio frequency module comprising a radio frequency component and an integrated passive device disposed on a side of the radio frequency component;
at least one connection member, wherein the integrated passive device is electrically connected to the substrate through the connection member and the connection member is a solder ball or a bump;
a first communication component, disposed on the integrated passive device or the substrate;
a second communication component, disposed on the integrated passive device or the substrate; and
an encapsulant, encapsulating at least the integrated passive device, the radio frequency component, a part of the substrate and one of the first and second communication components.

2. (canceled)

3. The electronic apparatus according to claim 1, wherein the baseband module further comprises a memory device electrically connected to the substrate, wherein the memory device and the radio frequency module are respectively disposed on different sides of the substrate.

4. The electronic apparatus according to claim 1, wherein the baseband module further comprises a memory device electrically connected to the substrate, wherein the memory device and the first communication component are respectively disposed on different sides of the substrate.

5. The electronic apparatus according to claim 1, wherein the baseband module further comprises a passive device electrically connected to the substrate, wherein the passive device and the baseband component are respectively disposed on different sides of the substrate.

6. The electronic apparatus according to claim 1, wherein the baseband module further comprises a passive device electrically connected to the substrate, wherein the passive device and the second communication component are disposed on a same side of the substrate.

7. The electronic apparatus according to claim 1, wherein the substrate has at least one embedded electronic element.

8. The electronic apparatus according to claim 1, wherein the first communication component comprises an antenna connector disposed on the substrate.

9. The electronic apparatus according to claim 8, wherein the first communication component comprises a first antenna component, wherein the antenna connector enables the first antenna component to be fixed on the substrate.

10. The electronic apparatus according to claim 1, wherein the first communication component is a chip antenna or an F-shaped circuit antenna.

11-12. (canceled)

13. The electronic apparatus according to claim 1, wherein the second communication component comprises an antenna connector disposed on the integrated passive device.

14. The electronic apparatus according to claim 13, wherein the second communication component further comprises a second antenna component, wherein the antenna connector enables the second antenna component to be fixed on the integrated passive device.

15. The electronic apparatus according to claim 1, wherein the radio frequency component is disposed between the integrated passive device and the baseband module.

16. The electronic apparatus according to claim 1, wherein the integrated passive device is disposed between the radio frequency component and the baseband module.

17. The electronic apparatus according to claim 1, wherein the second communication component is a chip antenna or an F-shaped circuit antenna.

18-20. (canceled)
